(19) United States
(12) Patent Application Publication
(10) Pub. No.: US 2016/0116361 A1
(43) Pub. Date: Apr. 28, 2016

(54) SYSTEM FOR WAFER-LEVEL TESTING OF MEMS PRESSURE SENSORS

(71) Applicant: FREESCALE SEMICONDUCTOR, INC., Austin, TX (US)

(72) Inventors: BRUNO J. DEBEURRE, PHOENIX, AZ (US); ALBERT S. CHECKANOV, CHANDLER, AZ (US); JANSEN D. CURRENS, GILBERT, AZ (US); PETER T. JONES, SCOTTSDALE, AZ (US); WILLIAM D. MCWHORTER, GOODYEAR, AZ (US); RAIMONDO P. SESSEGO, CHANDLER, AZ (US)

(21) Appl. No.: 14/525,408

(22) Filed: Oct. 28, 2014

(51) Int. Cl. G01L 27/00; B81C 99/00

(52) U.S. Cl. CPC G01L 27/00; B81C 99/0045; B81C 99/005

(57) ABSTRACT

A system for testing pressure sensors on a device wafer includes a tray for holding the device wafer. The tray includes a base having a surface, a spacer extending from the surface, and a tacky material disposed on the surface. The spacer holds the device wafer spaced apart from the surface of the base to form a chamber between the surface and the device wafer. A wafer chuck retains the tray and the device wafer under vacuum. The system further includes a nozzle and a seal element in fixed engagement with the nozzle. The seal element surrounds the outlet of the nozzle and is adapted for mechanical contact with the device wafer. An actuator is configured to place the nozzle and a diaphragm of one of the pressure sensors in proximity to one another, wherein a pneumatic pressure stimulus is applied to the diaphragm via an outlet of the nozzle.

### TECHNICAL FIELD OF THE INVENTION

The present invention relates generally to microelectromechanical systems (MEMS) sensors. More specifically, the present invention relates to a system for wafer-level testing of devices on a wafer, such as MEMS pressure sensors.

### BACKGROUND OF THE INVENTION

Wafer-level testing is sometimes used in the semiconductor industry for evaluating results of wafer processing and for the selection of devices for assembly. Electrical testing of integrated circuits can, in some instances, provide sufficient information for selecting good chips. However, with MEMS devices, additional mechanical, optical, chemical, or other stimulus may be needed in order to verify proper functionality of MEMS devices and make sure that their parameters fall within the design specification.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, the Figures are not necessarily drawn to scale, and:

FIG. 1 shows a simplified top view of a device wafer having microelectromechanical systems (MEMS) devices formed thereon;

FIG. 2 shows a side view of the device wafer along section lines 2-2 in FIG. 1;

FIG. 3 shows a block diagram of an exemplary test system for performing wafer-level testing of the wafer of FIG. 1;

FIG. 4 shows a top perspective view of a tray that may be utilized in the test system of FIG. 3;

FIG. 5 shows a bottom view of the tray of FIG. 4;

FIG. 6 shows a top perspective view of the tray with a device wafer loaded into it;

FIG. 7 shows a side sectional view of the tray and device wafer across section lines 7-7 of FIG. 6; and

FIG. 8 shows an enlarged partial view of the test system with a nozzle utilized to apply a pneumatic pressure stimulus the pressure sensors formed on the MEMS device wafer.

### DETAILED DESCRIPTION

In overview, embodiments of the present invention entail a test system for testing microelectromechanical systems (MEMS) devices at wafer-level. Such wafer-level testing provides the capability of determining critical mechanical and electrical characteristics of the MEMS devices, for example, MEMS pressure sensor devices. Embodiments implement a specialized tray fixture within the test system for holding a device wafer in vacuum. The tray has a chamber with a surface having a tacky coating used to trap eventual debris from the testing. Any debris generated during device testing is effectively contained within the chamber in order to prevent damage to other devices on the wafer and/or to prevent damage to or contamination of the environment outside of the tray. A pressure nozzle enables delivery of a high pneumatic pressure stimulus and has an effective seal adapted for mechanical contact with the device wafer. Implementation of the test system, including the tray and specialized nozzle, enable effective testing of, for example, individual pressure sensor devices at wafer-level. By utilizing the test system, functional testing of MEMS pressure sensor devices at wafer-level can decrease the cost of the final product by rejecting bad MEMS pressure sensor devices before any assembly steps and/or for providing quick feedback to a product line.

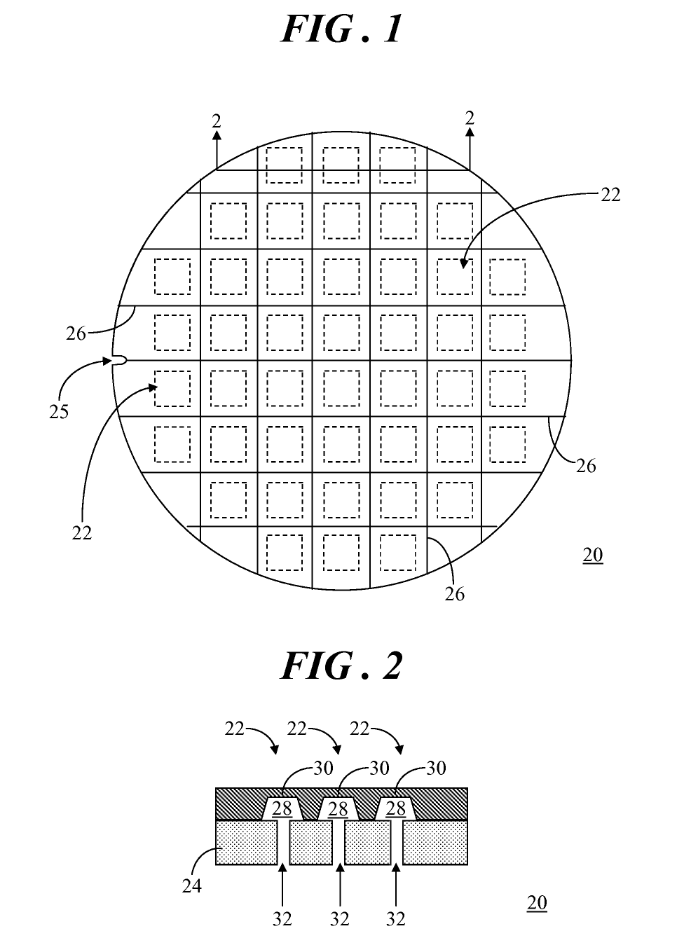

Referring to FIGS. 1 and 2, FIG. 1 shows a simplified top view of a MEMS device wafer 20 having a plurality of MEMS devices 22 formed thereon, and FIG. 2 shows a simplified side view of device wafer 20 along section lines 2-2 in FIG. 1. MEMS devices 22 (represented by dashed line squares in FIG. 1) may be formed in or on a substrate 24 by, for example, bulk or surface micromachining in accordance with known methodologies. MEMS device wafer 20 may have a notch 25 extending into wafer 20 from the perimeter of wafer 20. Notch 25 can be used by a test system (discussed below) to facilitate alignment of MEMS device wafer 20 within a test system.

Boundaries of each of MEMS devices 22 are delineated in FIG. 1 by scribe lines, also known as die streets 26. Per convention, following fabrication of MEMS devices 22, MEMS device wafer 20 is sawn, diced, or otherwise separated into individual dies, each of which contains one of MEMS devices 22. The individual MEMS devices 22 can be packaged with other MEMS devices, application specific integrated circuits, and so forth in accordance with a particular package design. MEMS device wafer 20 includes only a few MEMS devices 22 for simplicity of illustration. Those skilled in the art will readily recognize that MEMS device wafer 20 can include any quantity of MEMS devices 22 in accordance with the diameter of substrate 24, the capability of a particular fabrication plant, and/or the size of MEMS devices 22.

In an embodiment, MEMS devices 22 are pressure sensors, each having, for example, a pressure cavity 28 and a membrane element, referred to as a diaphragm 30, that deflects under pressure. Accordingly, MEMS devices 22 are referred to hereinafter as MEMS pressure sensors 22. A port 32 may extend through substrate 24 into each pressure cavity 28. These ports 32 may be utilized to facilitate fabrication of diaphragm 30 and pressure cavity 28 in connection with micromachining techniques. In accordance with an embodiment, ports 32 can additionally be used for various wafer-level test methodologies. Following the wafer-level test processes, ports 32 may be utilized in a differential pressure sensor configuration.

It should be understood that the use of relational terms, such as first and second, top and bottom, proximal and distal, and the like may be used herein to solely distinguish one entity or action from another without necessarily requiring or implying any actual such relationship, prioritization, or sequential order between such entities or actions. In addition, FIG. 2 and subsequent FIGS. 4-8 are illustrated using various shading and/or hatching to distinguish the various elements from one another for clarity of illustration.

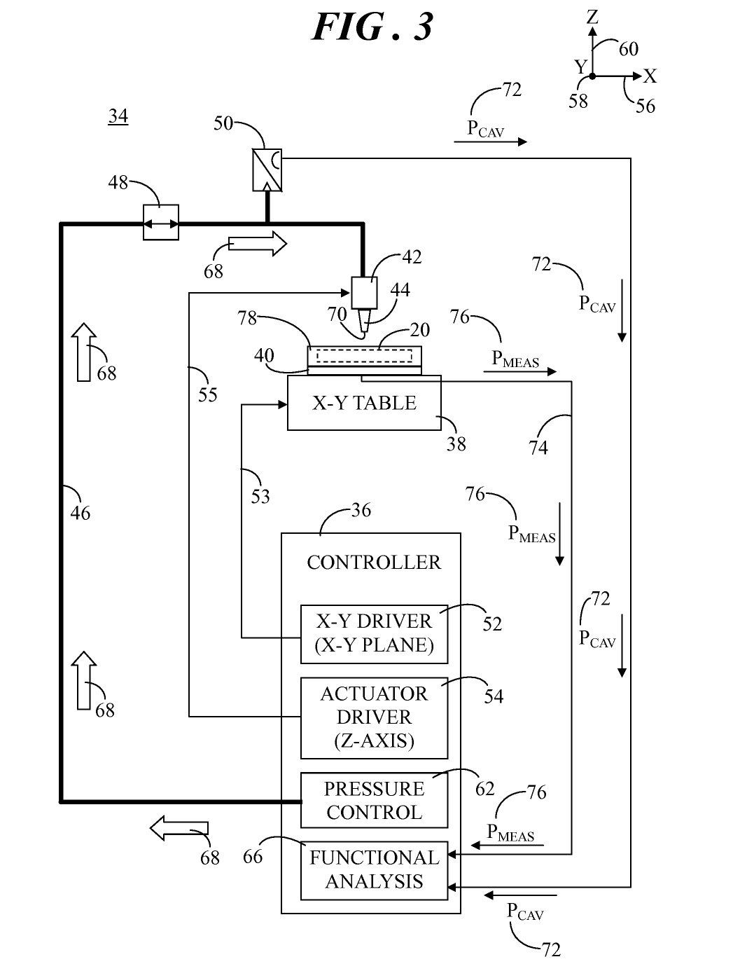

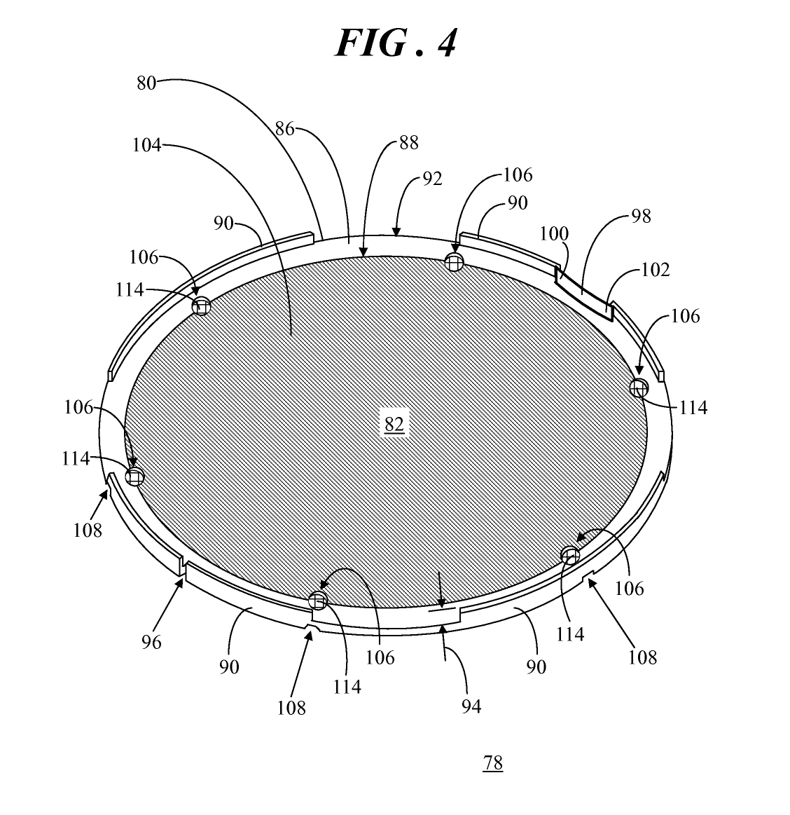

FIG. 3 shows a block diagram of an exemplary test system 34 for performing wafer-level testing of MEMS device wafer 20 (FIG. 1). Test system 34 generally includes a controller 36 and a movable X-Y stage referred to herein as an X-Y table 38. A wafer chuck 40 is coupled to X-Y table 38. Test system 34 further includes an actuator 42 having a nozzle 44, a fluid supply line 46 in communication with actuator 42, a nozzle valve 48, and an in-line pressure sensor 50. In accordance with an embodiment, test system 34 further includes a tray 78 configured to hold MEMS device wafer 20, and wafer chuck 40 is adapted to retain a tray 78 and MEMS device wafer 20 under vacuum, as will be discussed in connection with FIGS. 4-8. MEMS device wafer 20 may be largely encircled by tray 78. Therefore, MEMS device wafer 20 is represented in FIG. 3 by a dashed line box.

Controller 36 includes an X-Y driver module 52 in communication with X-Y table 38 via a signal line 53. X-Y driver module 52 is adapted to provide control signals to X-Y table 38 in order to move (i.e., index) X-Y table 36 substantially parallel to an X-Y plane of test system 34. Controller 36 additionally includes an actuator driver module 54 in communication with actuator 42 via a signal line 55. In an embodiment, actuator driver module 54 is adapted to provide control signals to actuator 42 in order to move actuator 42 and nozzle 44 in proximity to wafer 20. More particularly, actuator 42 and nozzle 44 are driven toward wafer 20 along an axis, e.g., the Z-axis, substantially perpendicular to the orientation of X-Y table 36. In the illustration of FIG. 3, a three-dimensional coordinate system is represented in which an X-axis 56 is oriented rightward and leftward on the page, a Y-axis 58 is directed inward into the page, and a Z-axis 60 is directed upward and downward on the page. Together, X-axis 56 and Y-axis 58 define the planar X-Y direction of movement of X-Y table 36, and Z-axis 60 defines the Z-axis direction of movement of nozzle 44.

An exemplary configuration is described in which actuator 42 undergoes Z-axis motion so as to move nozzle 44 toward MEMS device wafer 20. Movement of nozzle 44 toward MEMS device wafer 20 may be implemented to effectively apply mechanical pressure to MEMS device wafer 20 with little risk of breaking wafer 20. However, in an alternative embodiment, table 36 may be configured for three dimensional movement so as to move MEMS device wafer 20 toward nozzle 44. Still other hardware implementations may be utilized to provide the Z-axis motion so as to move nozzle 44 and MEMS device wafer 20 toward one another.

In-line pressure sensor 50 is in communication with fluid supply line 46 and is interposed between nozzle valve 48 and nozzle 44. In-line pressure sensor 50 is capable of detecting pressure within fluid supply line 46. As will be discussed below, pressure within fluid supply line 46 sensed by in-line pressure sensor 50 corresponds to a pressure within a cavity associated with one of MEMS pressure sensors 22 (FIG. 1) in response to a pneumatic pressure stimulus (discussed below). In this differential pressure sensor example, the cavity associated with one of MEMS pressure sensors 22 is pressure cavity 28 (FIG. 2) of one of MEMS pressure sensors 22 (FIG. 1). Therefore, the pressure sensed by in-line pressure sensor 50 corresponds to the pressure applied to diaphragm 30 from within pressure cavity 28. The sensed pressure may be utilized to ascertain the strength and stiffness of diaphragm 30 (FIG. 2) of each of MEMS pressure sensors.

Controller 36 further includes a pressure control module 62 and a functional analysis module 66. Pressure control module 62 is adapted to control a magnitude of a pneumatic pressure stimulus 68 communicated via fluid supply line 46 to an outlet 70 of nozzle 44. Functional analysis module 66 is in communication with in-line pressure sensor 50 and is adapted to receive a pressure signal 72, labeled P_{CAV}, corresponding to a magnitude of a cavity pressure within one of pressure cavities 28. Functional analysis module 66 may also be in communication with a probe system, a wiring bus 74 connected to X-Y table 38, or any other structure for conveying an output pressure signal 76, labeled P_{MEAS}, from at least one of MEMS pressure sensors 22 to functional analysis module 66.

It should be understood that X-Y driver 52, actuator driver 54, pressure control module 62 and functional analysis module 66 may be implemented in software, hardware, or a combination of software and hardware. Additionally, although controller 36 is shown to include each of X-Y driver 52, actuator driver 54, pressure control module 62 and functional analysis module 66, it should be understood that elements 52, 54, 62, and 66 may be implemented in more than one controller or processor located proximate to or more distant from X-Y table 38.

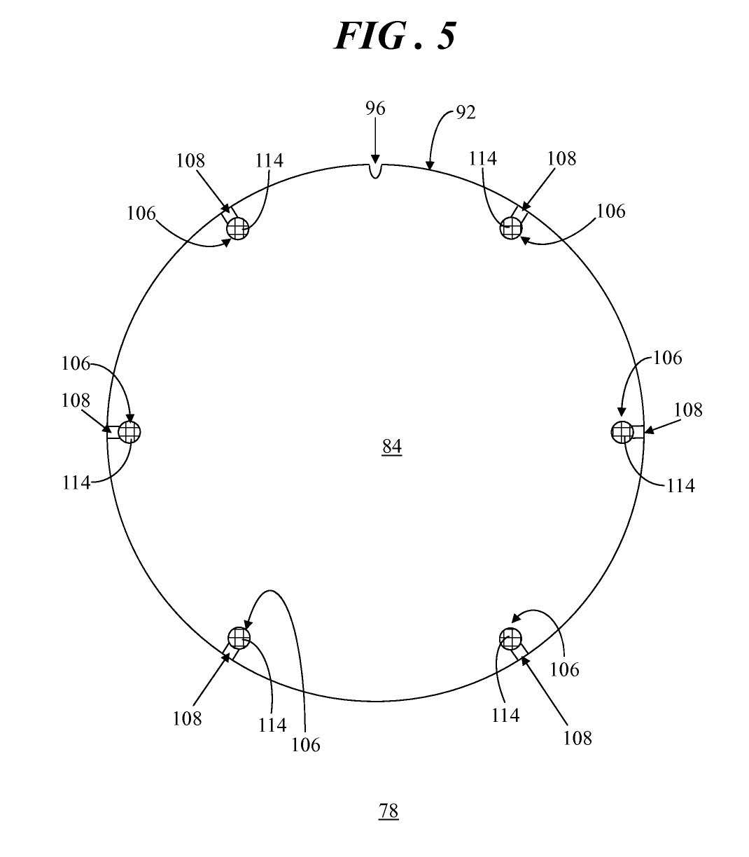

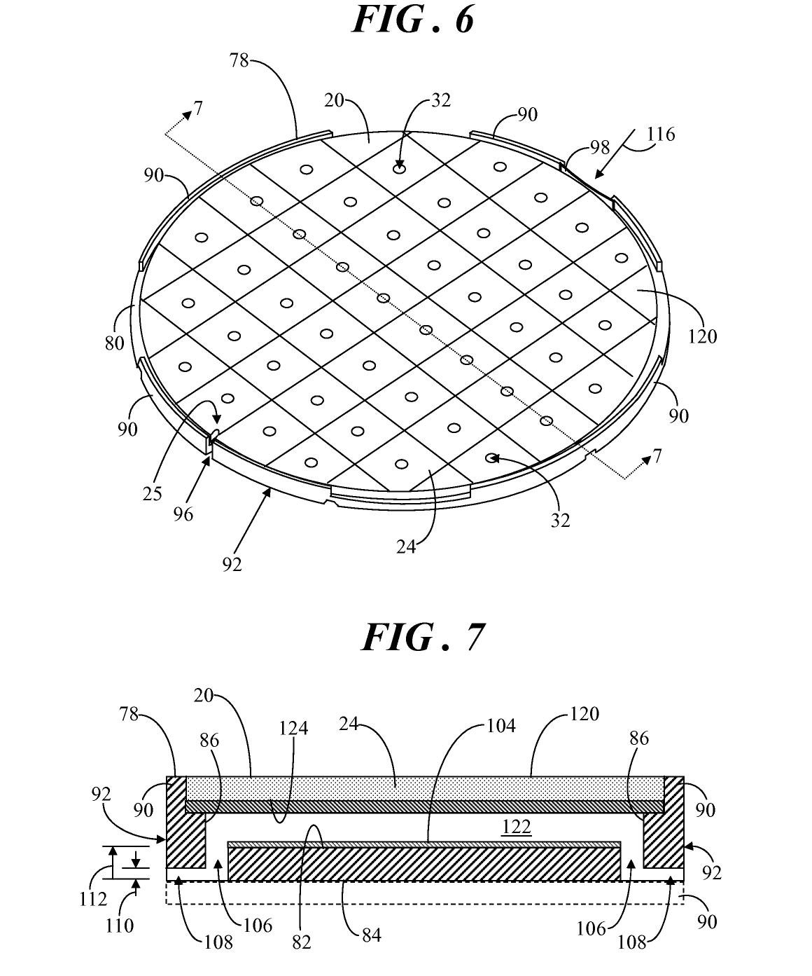

Referring to FIGS. 4 and 5, FIG. 4 shows a top perspective view of tray 78 that may be utilized in the test system 34 (FIG. 3), and FIG. 5 shows a bottom view of tray 78. Tray 78 is implemented within test system 34 to securely hold MEMS device wafer 20 (FIG. 1) in vacuum on wafer chuck 40 (FIG. 3), which itself is held on X-Y table. Although tray 78 may be utilized with test system 34, it should be understood that tray 78 may alternatively be utilized in connection with other commercial off-the-shelf and/or specialized test systems, or probers. The following discussion provides a general description of the various features of tray 78. The function of those various features will be described in connection with FIGS. 6-8.

Tray 78 includes a base 80 having a first (i.e., top) surface 82 and a second (i.e., bottom) surface 84. A spacer 86, or riser, extends from first surface 82 of base 80. In an embodiment, spacer 86 is located at a perimeter 88 of first surface 82 of base 80. Spacer 86 is configured to hold MEMS device wafer 20 above first surface 82 of base 80.

Tray 78 further includes a rim 90 located at an outer perimeter 92 of base 80. Rim 90 exhibits a height 94 above first surface 82 of base 80 and above spacer 86. In some embodiments, rim 90 does not fully encircle the entirety of base 80. Rather, rim 90 may be discontinuous. That is, rim 90 may not be present at certain locations about outer perimeter 92. As shown, a notch 96 extends through rim 90 from outer perimeter 92 of base 80. Additionally, a spring element 98 has opposing ends 100, 102 coupled to rim 90 and extending inwardly from rim 90.

In some embodiments, tray 78 further includes a tacky material 104 disposed on first surface 82 of base 80. Tacky material 104 may be, for example, a thermoplastic elastomer such as a styrene block copolymer. A styrene block copolymer (SBC) possesses the physical properties of rubber and the processing characteristics of thermoplasts. SBC's are used in a number of end products including adhesives, sealants, and in coating applications. In one example, an SBC-based tacky material 104 may be sprayed on first surface 82 of base 80 and cured. A completed coating thickness may be approximately fifty microns. The SBC-based tacky material 104 can be soft and flexible, and have a superior tack and adhesive properties. Although an SBC-based tacky material 104 is discussed herein, those skilled in the art will recognize that alternative tacky materials may be utilized as well.

Tray 78 additionally includes exhaust holes 106 extending through base 80 from first surface 82 to second surface 84. In this illustration, exhaust holes 106 are located at perimeter 88 of first surface 82. A groove 108 extends from each exhaust hole 106 along second surface 84 of base 80 to outer perimeter 92 of base 80. Each groove 108 extends a depth 110 (see FIG. 7) into base 80 that is less than a thickness 112 (see FIG. 7) of base 80. That is, grooves 108 are formed in second surface 84 but do not penetrate through the entire thickness 112 of base 80. In some embodiments, a screen 114 extends across each of exhaust holes 106 at first surface 82 of base 80. In other embodiments, screen 114 may extend across holes 106 and grooves 108 at second surface 84 and at outer perimeter 92 of base 80. Screens 114 may be suitably selected to largely prevent debris (discussed below) from escaping through exhaust holes 106 and grooves 108.

Referring to FIG. 6 FIG. 6 shows a top perspective view of tray 78 with a device wafer, e.g., MEMS device wafer 20, loaded into it. In an embodiment, MEMS device wafer 20 is loaded into tray 78 with notch 25 of MEMS device wafer 20 aligned with notch 96 in tray 78. As such, tray 78 holding MEMS device wafer 20 will appear as a single entity to test system 34.

MEMS device wafer 20 may be loaded into tray 78 manually or via automated equipment. The discontinuity in, i.e., the absence of, rim 90 at certain locations about outer perimeter 92 of base 80 allows space for the automated equipment to grasp edge 118 of MEMS device wafer 20 at multiple locations. It should be observed in FIG. 6 that spring element 98, extending inwardly from rim 90 of tray 78 applies a retaining force, represented by an arrow 116, against an edge 118 of MEMS device wafer 20 to secure MEMS device wafer 20 within tray 78. In the illustrated example, MEMS device wafer 20 is loaded into tray 78 with MEMS pressure sensors 22 (not visible) facing downwardly so that an outer surface 120 of substrate 24 is facing upwardly. Thus, ports 32 extending through substrate 24 are exposed.

FIG. 7 shows a side sectional view of tray 78 and MEMS device wafer 20 across section lines 7-7 of FIG. 6. When MEMS device wafer 20 is loaded into tray 78, a portion of MEMS device wafer 20 (the outer perimeter in this example) rests on spacer 86. Thus, MEMS device wafer 20 is held in tray 78 spaced apart from first surface 82 of base 80 so that a chamber 122 is formed between first surface 82 and a device side 124 of MEMS device wafer 20. Since holes 106 extend through base 80 from first surface 82 to second surface 84, chamber 122 is therefore connected to exhaust holes 106 and grooves 108. Additionally, device side 124 of MEMS device wafer 20 faces tacky material 104 applied to first surface 82 of base 80.

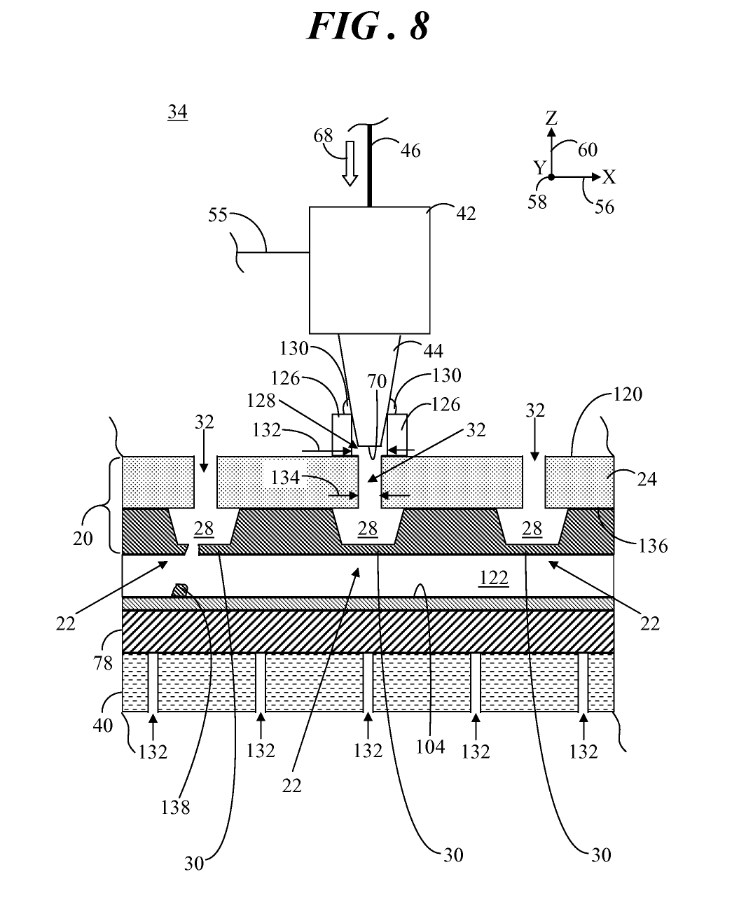

It should be observed that grooves 108 extend through outer perimeter 92 of base 80. When tray 78 is retained on wafer chuck 40 (shown in dashed line form in FIG. 7), grooves 108 will not intersect with vacuum openings 132 (see FIG. 8) in wafer chuck 40. Instead, the openings of grooves 108 at outer perimeter 92 can serve as exhaust ports for chamber 122.

FIG. 8 shows an enlarged partial view of test system 34 with nozzle 44 utilized to apply pneumatic pressure stimulus 68 to MEMS pressure sensors 22 formed on MEMS device wafer 20. In particular, MEMS device wafer 20 is held in tray 78, and the combination of tray 78 with MEMS device wafer 20 is retained under vacuum on wafer chuck 40. Only a few MEMS pressure sensors 22 and a portion of MEMS device wafer 20 are shown for simplicity of illustration in the partial enlarged view of FIG. 8. Additionally, test system 34 is shown with a single nozzle 44 for simplicity of illustration. In alternative embodiments, test system 34 may include multiple nozzles and associated components so that multiple MEMS pressure sensors 22 may be concurrently tested. In an embodiment, nozzle 44 is directed by signals received via signal line 55 to move along Z-axis 60 toward port 32 in substrate 24 of MEMS device wafer 20. Test system 34 further includes a seal element 126 surrounding outlet 70 of nozzle 44. An opening 128 extends through seal element 126 in which outlet 70 of nozzle 44 is located.

Seal element 126 is in fixed engagement with nozzle 44. In some embodiments, seal element 126 may be fixed to nozzle 44 using a thermosetting resin epoxy 130. However, other adhesive materials and/or mechanical components may be used. Mechanical components entail, for example, clamps, a flange extending outwardly from the outer surface of nozzle 44, or other such features that largely prevent slippage of seal element 126 relative to nozzle 44. Seal element 126 may be formed such that a diameter 132 of opening 128 extending through seal element 126 is larger than a diameter 134 of port 32. This difference in diameters 132, 134 accommodates slight variations in fabrication dimensions between various MEMS pressure sensors 22, such as differences in diameters 134 of ports 32 and/or differences in distances between ports 32.

In the illustrated example, MEMS pressure sensors 22 are located on one side 136 of substrate 24, and seal element 126 is adapted for mechanical contact with the opposing side (i.e., outer surface 120) of substrate 24 surrounding port 32. As nozzle 44 is driven toward substrate 24, mechanical force is applied to seal element 126 to form a pressure seal between surface 120 of substrate 24 and seal element 126. Accordingly, pressure cavity 28 at least temporarily becomes a sealed pressure chamber for purposes of wafer-level testing. Thus, pneumatic pressure stimulus 68 can be applied to diaphragm 30 via port 32 and into the sealed pressure cavity 28.

In general, the pressure within sealed pressure cavity 28 changes in response to pneumatic pressure stimulus 68, and this pressure, i.e., pressure signal 72 (FIG. 3), can be detected by inline pressure sensor 50 and can be used to test the strength and/or stiffness of diaphragm 30. By way of example, a pressure sensor strength test may be performed on MEMS device wafer 20. A pressure sensor strength test may be a destructive test executed at wafer-level to identify those MEMS pressure sensors 22 having diaphragms 30 of insufficient strength of withstand a particular design pressure.

Referring concurrently to FIGS. 3 and 8, execution of a pressure sensor strength test can entail retaining MEMS device wafer 20 in wafer chuck 40 of X-Y table 38. More particularly, MEMS device wafer 20 is held in tray 78. Tray 78 with MEMS wafer 20 is installed on wafer chuck 40, and vacuum is drawn via vacuum openings 132 in wafer chuck 40 in accordance with known procedures and structures to retain tray 78 and MEMS wafer 20 on wafer chuck 40. X-Y table 38 may be indexed, or moved, along X-axis 56 and/or Y-axis 58 to place one of MEMS pressure sensors 22 in proximity to nozzle 44. Once one of MEMS pressure sensors 22 is placed in proximity to nozzle 44, port 32 of MEMS pressure sensor 22 is sealed to form a sealed pressure cavity 28. More particularly, as nozzle 44 is moved along Z-axis 60 toward MEMS device wafer 20, seal element 126 is positioned surrounding port 32 and is placed in contact with outer surface 120 of substrate 24. Force is then applied to seal element 126 to form a pressure seal between outer surface 120 of substrate 24 and seal element 126, thereby forming a sealed pressure cavity 28.

Thereafter, pneumatic pressure stimulus 68 can be applied to diaphragm 30 of the particular MEMS pressure sensor 22 under test via port 32 and pressure cavity 28. Pneumatic pressure stimulus 68 may be air or another suitable fluid material that is provided via fluid supply line 46 from pressure control module 62 of controller 36, or a subsystem associated with pressure control module 62. The magnitude or level of pneumatic pressure stimulus 68 applied to MEMS pressure sensor 22 may be at least equivalent to or greater than a maximum pressure rating for MEMS pressure sensors 22. The maximum pressure rating may be a design parameter specific to MEMS pressure sensors 22. Stress is applied to diaphragm 30 by outputting pneumatic pressure stimulus 68 from outlet 70 of nozzle 44 through port 32 and into pressure cavity 28.

After a pre-determined settling time, pressure in pressure cavity 28 can be measured. The pressure in pressure cavity 28 is the pressure imposed upon diaphragm 30 by pneumatic pressure stimulus 68. That is, nozzle valve 48 may be closed so that following closure of nozzle valve 48, a closed system is produced between nozzle valve 48 and diaphragm 30. In-line pressure sensor 50, located between nozzle valve 48 and diaphragm 30 can be used to measure the pressure in that portion of fluid supply line 46. Due to the closed system configuration, the pressure in fluid supply line 46 downstream from nozzle valve 48 will be substantially the same as the magnitude of the pressure in pressure cavity 28, which is the pressure imposed upon diaphragm 30. In-line pressure sensor 50 produces cavity pressure signal 72, which can be communicated to functional analysis module 66.

At functional analysis module 66, a determination can be made as to whether cavity pressure signal 72 is outside of a passing range. In this example, when cavity pressure signal 72 is greater than a low pressure threshold value then a conclusion can be reached that diaphragm 30 was not broken, cracked, or otherwise breached prior to or during the application of pneumatic pressure stimulus 68. Alternatively, when cavity pressure signal 72 is less than the low pressure threshold value then a conclusion can be reached that diaphragm 30 was broken, cracked, or otherwise breached prior to or during the application of pneumatic pressure stimulus 68. Following testing, seal element 136 is released and nozzle 44 is moved along Z-axis 60 away from the particular MEMS pressure sensor 22 under test. When there is another MEM pressure sensor 22 to be tested on MEMS device wafer, X-Y table 38 is indexed to the next MEMS pressure sensor 22 and testing for the next MEMS pressure sensor 22.

Once all MEMS pressure sensors 22 on MEMS wafer device 20 have been tested, the pressure sensor strength test process ends for that particular MEMS device wafer 20. A pressure sensor strength test process is generally described herein for illustrative purpose. It should be understood, however, that test system 34, including tray 78 and the specialized nozzle 44 and seal element 126, may be used for other wafer-level testing. This other wafer-level testing may entail testing of diaphragm stiffness and/or determining calibration parameters for each of MEMS pressure sensors 22 on MEMS wafer device.

As mentioned above, sometimes one of diaphragms 30 may be broken during testing. This is represented by the leftmost one of pressure sensors 22 shown in FIG. 8. When diaphragm 30 breaks, some debris 138 can be produced. In accordance with an embodiment, pneumatic pressure stimulus 68 exiting from pressure cavity 28 through the breach in diaphragm 30 will blow debris 138 toward base 80 of tray 78. This debris 138 will become at least temporarily adhered to tacky material 104 within chamber 122, thereby largely preventing debris 138 in chamber 122 from damaging other MEMS pressure sensors 22 in MEMS device wafer 20.

Pneumatic pressure stimulus 68 exiting from pressure cavity 28 through the breach in diaphragm 30 can be exhausted from chamber 122 and tray 78 via exhaust holes 106 and grooves 108 (FIG. 4) toward the exhaust ports in outer perimeter 92 (FIG. 7) of base 80. It should be recalled that screen material 114 may seal exhaust holes 106 and grooves 108. Therefore, debris 138 will largely be prevented from exiting chamber 122 and contaminating the surroundings in which tray 78 is located.

Following testing of each of MEMS pressure sensors 22 on MEMS wafer device 20, MEMS wafer device 20 can be removed from tray 78. Thereafter, tray 78 may be cleaned by, for example, rinsing away debris 138 from top surface 82 of tray 78. Tray 78 may subsequently be reused for testing another MEMS wafer device. When tacky material 104 eventually loses its adhesive properties after multiple uses, tacky material 104 may be removed and a new coating of tacky material 104 may be applied to tray 78.

Thus, various embodiments of a test system for wafer-level testing and a specialized tray fixture implemented within the test system have been described. An embodiment of a tray configured to hold a device wafer comprises a base having a first surface and a spacer extending from the first surface of the base. The spacer is configured to hold the device wafer spaced apart from the first surface of the base to form a chamber between the first surface and the device wafer.

An embodiment of a system for testing pressure sensors on a device wafer, each of the pressure sensors including a diaphragm, comprises a tray configured to hold the device wafer. The tray includes a base having a first surface, a spacer extending from the first surface of the base, and a tacky material disposed on the first surface of the base, wherein the spacer is configured to hold the device wafer spaced apart from the first surface of the base to form a chamber between the first surface and the device wafer. The system further comprises a wafer chuck adapted to retain the tray and the device wafer under vacuum, a nozzle for providing a pneumatic pressure stimulus, a seal element in fixed engagement with the nozzle, the seal element surrounding the outlet of the nozzle, and the seal element being adapted for mechanical contact with the device wafer, and an actuator for placing the nozzle and the diaphragm of one of the pressure sensors in proximity to one another, wherein the pneumatic pressure stimulus is applied to the diaphragm of the one of the pressure sensors via an outlet of the nozzle.

The seal element provides an effective seal mechanism for forming a sealed pressure cavity and the nozzle enables delivery of the pneumatic pressure stimulus within the sealed pressure cavity. The tacky material within the chamber can trap eventual debris from the testing, and any debris generated during device testing is thus effectively contained within the chamber in order to prevent damage to other devices on the wafer and/or to prevent damage or contamination of the environment outside of the tray. Implementation of the test system, including the tray and specialized nozzle, enables effective testing of, for example, individual pressure sensor devices at wafer-level. Such wafer-level testing provides the capability of determining critical mechanical and electrical characteristics of the MEMS devices, for example, MEMS pressure sensor devices. By utilizing the test system and performing functional testing of MEMS pressure sensor devices at wafer-level, the cost of the final product may be reduced by rejecting bad MEMS pressure sensor devices before any assembly steps. Additionally, utilizing the test system to perform wafer-level testing can provide quick feedback to a product line.

While the principles of the inventive subject matter have been described above in connection with specific systems, apparatus, and methods, it is to be clearly understood that this description is made only by way of example and not as a limitation on the scope of the inventive subject matter. Further, the phraseology or terminology employed herein is for the purpose of description and not of limitation.

The foregoing description of specific embodiments reveals the general nature of the inventive subject matter sufficiently so that others can, by applying current knowledge, readily modify and/or adapt it for various applications without departing from the general concept. Therefore, such adaptations and modifications are within the meaning and range of equivalents of the disclosed embodiments. The inventive subject matter embraces all such alternatives, modifications, equivalents, and variations as fall within the spirit and broad scope of the appended claims.

What is claimed is:

1. A tray configured to hold a device wafer comprising:
a base having a first surface; and
a spacer extending from said first surface of said base, wherein said spacer is configured to hold said device wafer spaced apart from said first surface of said base to form a chamber between said first surface and said device wafer.

2. The tray of claim 2 wherein said spacer is located at a perimeter of said first surface of said base.

3. The tray of claim 1 wherein an exhaust hole extends through said base from said first surface to a second surface of said base.

4. The tray of claim 3 wherein said tray further comprises a groove extending from said exhaust hole along said second surface of said base to an outer perimeter of said tray, said groove extending a depth into said base that is less than a thickness of said base.

5. The tray of claim 4 further comprising a screen extending across at least one of said exhaust hole and said groove.

6. The tray of claim 1 further comprising a tacky material is disposed on said first surface of said base.

7. The tray of claim 1 further comprising a rim located at an outer perimeter of said base, said rim having a height that is adjacent to an edge of said device wafer when said device wafer is held in said tray.

8. The tray of claim 7 wherein said rim is discontinuous along said outer perimeter of said base.

9. The tray of claim 7 further comprising a spring element having opposing ends coupled to said rim, said spring element extending inwardly from said rim, and said spring element being configured to apply a retaining force to said edge of said device wafer.

10. The tray of claim 1 further comprising a notch extending from a perimeter of said base into said first surface, said notch being keyed to a wafer notch formed in said device wafer.

11. A system for testing pressure sensors on a device wafer, each of said pressure sensors including a diaphragm, and said system comprising:
a tray configured to hold said device wafer, said tray including a base having a first surface and a spacer extending from said first surface of said base, wherein said spacer is configured to hold said device wafer spaced apart from said first surface of said base to form a chamber between said first surface and said device wafer;
a wafer chuck adapted to retain said tray and said device wafer under vacuum;
a nozzle for providing a pneumatic pressure stimulus; and
an actuator for placing said nozzle and said diaphragm of one of said pressure sensors in proximity to one another, wherein said pneumatic pressure stimulus is applied to said diaphragm of said one of said pressure sensors via an outlet of said nozzle.

12. The system of claim 11 wherein said tray further comprises:
at least one exhaust hole extending through said base from said first surface to a second surface; and
a groove extending from said exhaust hole along said second surface of said base to an outer perimeter of said tray, said groove extending a depth into said base that is less than a thickness of said base.

13. The system of claim 11 wherein said tray further comprises a tacky material disposed on said first surface of said base.

14. The system of claim 11 wherein said tray further comprises a rim located at an outer perimeter of said base, said rim having a height that is adjacent to an edge of said device wafer when said device wafer is held in said tray.

15. The system of claim 14 wherein said rim is discontinuous along said outer perimeter of said base.

16. The system of claim 14 further comprising a spring element having opposing ends coupled to said rim, said spring element extending inwardly from said rim, and said spring element being configured to apply a retaining force to an edge of said device wafer.

17. The system of claim 11 further comprising a notch extending from a perimeter of said base into said first surface, said notch being keyed to a wafer notch formed in said device wafer.

18. The system of claim 11 further comprising a seal element in fixed engagement with said nozzle, said seal element surrounding said outlet of said nozzle, and said seal element being adapted for mechanical contact with said device wafer.

19. The system of claim 11 further comprising:
a fluid supply line in communication with said nozzle for providing said pneumatic pressure stimulus;
a pressure transducer for measuring a pressure within said fluid supply line in response to said pneumatic pressure stimulus, said pressure being indicative of a cavity pressure within a cavity associated with said one of said pressure sensors; and
a controller configured to receive said pressure and ascertain functionality of said one of said pressure sensors in response to said pressure.

20. A system for testing pressure sensors on a device wafer, each of said pressure sensors including a diaphragm, and said system comprising:
a tray configured to hold said device wafer, said tray including a base having a first surface, a spacer extending from said first surface of said base, and a tacky material disposed on said first surface of said base, wherein said spacer is configured to hold said device wafer spaced apart from said first surface of said base to form a chamber between said first surface and said device wafer;
a wafer chuck adapted to retain said tray and said device wafer under vacuum;
a nozzle for providing a pneumatic pressure stimulus;
a seal element in fixed engagement with said nozzle, said seal element surrounding an outlet of said nozzle, and said seal element being adapted for mechanical contact with said device wafer; and
an actuator for placing said nozzle and said diaphragm of one of said pressure sensors in proximity to one another, wherein said pneumatic pressure stimulus is applied to said diaphragm of said one of said pressure sensors via said outlet of said nozzle.
